(19) United States
(12) Patent Application Publication
(10) Pub. No.: US 2011/0048502 A1
(43) Pub. Date: Mar. 3, 2011

(54) Systems and Methods of Photovoltaic Cogeneration

(75) Inventors: Dan KIKINIS, Saratoga, CA (US); Earl G. POWELL, Sunnyvale, CA (US)

(73) Assignee: TIGO ENERGY, INC., Los Gatos, CA (US)

(21) Appl. No.: 12/712,152

(22) Filed: Feb. 24, 2010

Related U.S. Application Data
(60) Provisional application No. 61/275,394, filed on Aug. 28, 2009.

(51) Int. Cl. H01L 31/058; H01L 31/052

(52) U.S. Cl. 136/248; 136/246

(57) ABSTRACT

Systems and methods are disclosed for controlling photovoltaic cell temperature by removing excess thermal energy from photovoltaic cells in a photovoltaic module and using the excess thermal energy for heating or to drive a heating and/or cooling apparatus. In one instance, the heating and/or cooling apparatus is an absorption chiller. A generator of the absorption chiller can either be thermally connected to the photovoltaic module or can be heated by transferring the thermal energy from the photovoltaic module to the absorption chiller via a heating fluid such as water.

### CROSS-REFERENCE TO RELATED APPLICATIONS

The present application claims the benefit of Provisional U.S. Application Ser. No. 61/275,394, filed Aug. 28, 2009, and titled “System and Method for Novel Solar Panel Cogeneration and Efficiency Enhancement,” incorporated herein by reference.

### FIELD OF THE TECHNOLOGY

At least some embodiments of the disclosure relate to photovoltaic systems in general, and more particularly but not limited to, improving the energy production performance of photovoltaic systems.

### BACKGROUND

Photovoltaic cell efficiency decreases with increasing temperature. This effect can be mitigated by removing thermal energy from the photovoltaic cells. At the same time, cooling systems often use electricity or mechanical energy to generate cool air or fluid. However, some cooling systems use heat or thermal energy as the energy input. These cooling systems are useful where power is inconsistent or where there is an abundance of excess heat (e.g., turbine exhausts). Absorption chillers are one example of such cooling systems.

### SUMMARY OF THE DESCRIPTION

Systems and methods to cool solar cells and a structure using an absorption chiller to achieve both goals are described herein. Some embodiments are summarized in this section.

Solar cells generally work more efficiently when cooled to an optimum operating temperature. This disclosure discusses systems and method for removing excess heat, or thermal energy, from solar modules comprising solar cells and using that thermal energy for various applications. For instance, the thermal energy removed from a solar module can be used to drive a heating and cooling apparatus that uses thermal energy as an energy input. The thermal energy can also be used to directly heat a structure, object, or space (e.g., a home, office, or swimming pool, to name a few). The thermal energy can also be stored and used at a later time.

In one embodiment, a system can include a photovoltaic module, a thermal path, and an apparatus. The photovoltaic module can co-generate thermal energy (generate electricity and thermal energy). The thermal path can remove a portion of the thermal energy from the photovoltaic module. The apparatus can be at least partially driven by the portion of the thermal energy from the thermal path.

In another embodiment, an apparatus can include a photovoltaic module, a thermal energy absorption enclosure, and a heating fluid. The photovoltaic module can generate electricity and thermal energy. The thermal energy absorption enclosure can be in contact with the photovoltaic module. The heating fluid can pass through the thermal energy absorption enclosure and be configured to absorb a portion of the thermal energy and remove the portion of the thermal energy from the thermal energy absorption enclosure.

In another embodiment, a method includes removing thermal energy from a photovoltaic module and using the thermal energy to drive an apparatus.

Other embodiments and features of the present invention will be apparent from the accompanying drawings and from the detailed description which follows.

### BRIEF DESCRIPTION OF THE DRAWINGS

The embodiments are illustrated by way of example and not limitation in the figures of the accompanying drawings in which like references indicate similar elements.

FIG. 1a illustrates a system that includes a photovoltaic cogeneration unit thermally connected to a heating and/or cooling apparatus.

FIG. 1b illustrates an embodiment of the photovoltaic cogeneration unit 110 illustrated in FIG. 1.

FIG. 2 illustrates a system including an absorption chiller having a generator that is heated via thermal energy drawn from a photovoltaic module.

FIG. 3 is a detail view of an embodiment of the photovoltaic cogeneration unit illustrated in FIG. 2.

FIG. 4 illustrates one embodiment of an absorption chiller.

FIG. 5 illustrates a system including an absorption chiller located adjacent to a structure, and having a thermal energy input provided by a heating fluid that is heated via a photovoltaic cogeneration unit.

FIG. 6 is a detailed embodiment of the photovoltaic cogeneration unit illustrated in FIG. 5.

FIG. 7 illustrates an embodiment of a system for cooling a photovoltaic module.

FIG. 8 illustrates a method for cooling a solar module.

### DETAILED DESCRIPTION

The following description and drawings are illustrative and are not to be construed as limiting. Numerous specific details are described to provide a thorough understanding. However, in certain instances, well known or conventional details are not described in order to avoid obscuring the description. References to one or an embodiment in the present disclosure are not necessarily references to the same embodiment; and, such references mean at least one.

Photovoltaic systems tend to operate effectively in sunny locations (e.g., California, Arizona, Colorado, to name a few). Sunny locations also tend to be warm and utilize large amounts of electricity to power air conditioning or other cooling systems. Thus, cooling systems and photovoltaic systems are often found in the same locations, and often the photovoltaic systems generate the electricity that drives the cooling systems.

While sunlight provides energy to solar cells of photovoltaic systems, sunlight also decreases solar cell efficiency by heating the solar cells. As the semiconductors in solar cells are heated, solar cell voltage drops and less power can be generated. Natural convection cooling from the air generally fails to sufficiently cool solar cells. Solar cells can operate more efficiently if thermal energy (or heat) is removed from them. At the same time, there are cooling devices that use heat as an input rather than mechanical energy or electricity. One such category of cooling systems is an absorption chiller. By drawing heat out of solar cells and using that heat to drive an absorption chiller, solar cells can operate more efficiently and a cooling system can run off excess thermal heat that otherwise would not be used.

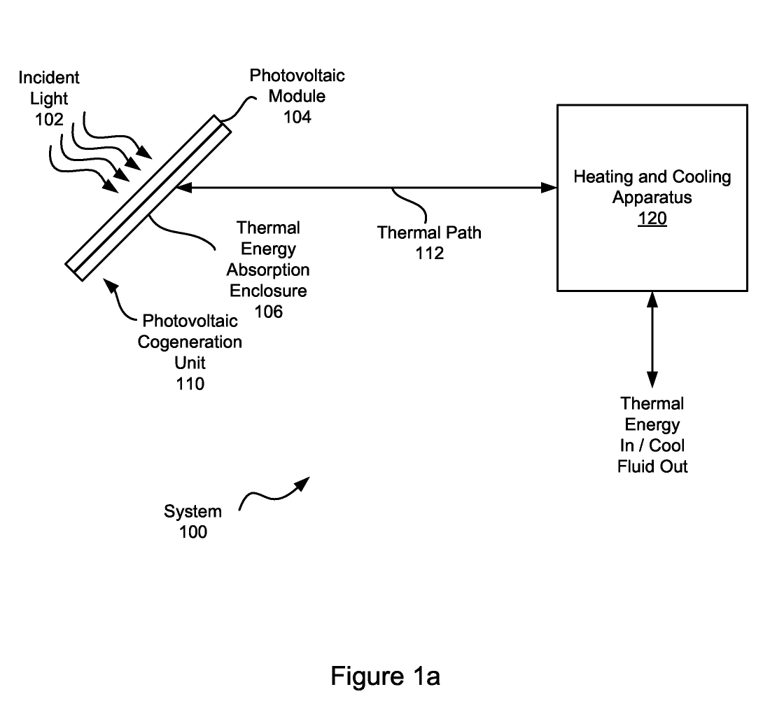

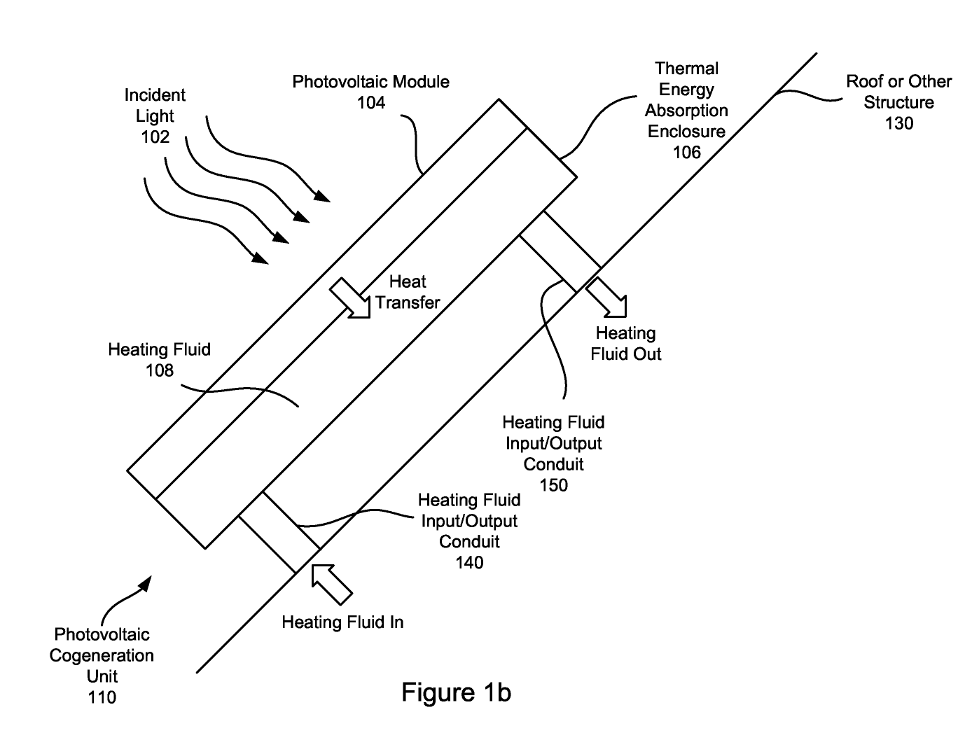

FIG. 1a illustrates a system 100 that includes a photovoltaic cogeneration unit 110 thermally connected to a heating and/or cooling apparatus 120. The photovoltaic cogeneration unit 110 includes a photovoltaic module 104 for generating electricity via absorbing incident light 102. The photovoltaic module 104 also generates thermal energy since not all of the absorbed light 102 is converted to electricity. This thermal energy can decrease the efficiency of the photovoltaic module 104, so a portion of the thermal energy can be transported (or removed or conveyed) to the heating and/or cooling apparatus 120. The heating and/or cooling apparatus 120 can use the portion of the thermal energy to drive a cooling cycle. In an embodiment, the heating and/or cooling apparatus 120 can use the portion of the thermal energy to drive a heating cycle or to directly heat a structure, object, or space. Removing the portion of the thermal energy from the photovoltaic module 104 and conveying the portion of the thermal energy to the heating and/or cooling apparatus 120 can control the temperature of the photovoltaic module 104. The heating and/or cooling apparatus 120 can generate cool fluid to be used to cool a structure, object, or space. The heating and/or cooling apparatus 120 can be at least partially driven by or use the thermal energy as an energy input rather than mechanical or electrical energy. Examples of such heating and/or cooling apparatuses include absorption chillers, adsorption chillers, solar air conditioning desiccant systems, and the heating and/or cooling apparatuses disclosed in at least the following: U.S. Pat. No. 4,438,633, U.S. Pat. No. 4,123,003, U.S. Pat. No. 4,007,776, and U.S. Pat. No. 4,023,948, the disclosures of which are incorporated herein by reference. The system 106 may also include a thermal energy absorption enclosure 106 in contact with the photovoltaic module 104. A heating fluid can pass through the thermal energy absorption enclosure 106 and absorb a portion of the thermal energy from the photovoltaic module 104. The heating fluid can then remove the portion of the thermal energy from the thermal energy absorption enclosure 106. The portion of the thermal energy can be transported from the photovoltaic cogeneration unit 110 to the heating and/or cooling apparatus 120 via a thermal path 112. The thermal path 112 can be a conduit (e.g., pipes) for the heating fluid.

The thermal energy absorption enclosure 106 can be configured to absorb a portion of the thermal energy from the photovoltaic module 104. The thermal energy absorption enclosure 106 is an apparatus able to allow the heating fluid to absorb the portion of the thermal energy while passing through the thermal energy absorption enclosure 106. In an embodiment, the thermal energy absorption enclosure 106 has input and output conduits configured to circulate the heating fluid into, through, and out of the thermal energy absorption enclosure 106. In an embodiment, the thermal energy absorption enclosure 106 is heating-fluid filled space between two plates. One of the plates can be made of a thermally-conductive material (e.g., steel or copper, to name two) and can be connected to or in contact with the photovoltaic module 104. In an embodiment, the thermal energy absorption enclosure 106 is a series of parallel, criss-crossing, or meandering conduits connected to the photovoltaic module 104. In an embodiment, the thermal energy absorption enclosure 106 is a part of the photovoltaic module 104. In an embodiment, a thermally conductive material or structure can be arranged between the photovoltaic module 104 and the thermal energy absorption enclosure 106. The thermally conductive material or structure can enhance the transfer of thermal energy between the photovoltaic module 104 and the thermal energy absorption enclosure 106. For instance, thermal paste or metallic heat fins can be arranged and in contact with the photovoltaic module 104 and the thermal energy absorption enclosure 106. Other materials and structures are also possible. While the heating fluid may fill the entire thermal energy absorption enclosure 106, this is not required. The pressure from the circulating heating fluid may be such that the heating fluid only partially fills the thermal energy absorption enclosure 106.

In an embodiment, the thermal energy absorption enclosure 106 is part of the heating and/or cooling apparatus 120. For instance, the heating and/or cooling apparatus 120 can be an absorption chiller, and the thermal energy absorption enclosure 106 can be a generator of the absorption chiller. Alternately, the thermal energy absorption enclosure 106 can have a heating fluid circulating through it that absorbs a portion of the thermal energy from the photovoltaic module 104. The heating fluid can circulate between the thermal energy absorption enclosure 106 and the heating and/or cooling apparatus 120 via the thermal path 112, thus transporting the portion of the thermal energy from the thermal energy absorption enclosure 106 to the heating and/or cooling apparatus 120. In an embodiment, the thermal path 112 comprises one or more conduits. The heating fluid circulates through the conduits and circulates between the thermal energy absorption enclosure 106 and the heating and/or cooling apparatus 120. Non-limiting examples of the heating fluid include water and steam.

In an embodiment, the heating and/or cooling apparatus 120 can remove the portion of the thermal energy from the photovoltaic module 104. In an embodiment, the heating and/or cooling apparatus 120 can be used to cool a structure, object, or space using the portion of the thermal energy as an energy input. In an embodiment, the heating and/or cooling apparatus 120 can be a heat exchanger for conveying the portion of the thermal energy from the photovoltaic cogeneration unit 110 to a structure, object, or space. In an embodiment, the heating and/or cooling apparatus 120 is an absorption chiller and includes a generator. The thermal energy absorption enclosure 106 can absorb the portion of the thermal energy from the photovoltaic module 104 via the heating fluid. The heating fluid can circulate between the thermal energy absorption enclosure 106 and the generator of the absorption chiller thus transporting the portion of the thermal energy from the thermal energy absorption enclosure 106 to the generator. The absorption chiller can use the portion of the thermal energy to remove thermal energy from a structure, object, or space (or to generate cool fluid used to cool a structure, object, or space).

In another embodiment, the generator can replace the thermal energy absorption enclosure 106. In other words, the generator can be integrated or attached to the photovoltaic module 104. The generator can control the temperature of the photovoltaic module 104 by absorbing the portion of the thermal energy from the photovoltaic module 104. The generator can use the portion of the thermal energy to separate a refrigerant and an absorbent via boiling the refrigerant out of solution. The generator can then transport the gaseous refrigerant back to a condenser of the absorption chiller via a gaseous refrigerant output conduit. The generator can transport the liquid refrigerant back to an absorber of the absorption chiller via a liquid absorbent output conduit.

In an embodiment where the heating and/or cooling apparatus is an absorption chiller, the portion of the thermal energy from the photovoltaic module 104 may not be sufficient to boil the refrigerant out of solution in the generator. The heating and/or cooling apparatus 120 can then include a heat exchanger (e.g., a solar collector or a solar thermal collector, to name two) that can absorb additional thermal energy from an external environment and transport the additional thermal energy to the generator. The combination of the portion of the thermal energy from the photovoltaic module 104 and the additional thermal energy from the heat exchanger may be sufficient to boil the refrigerant out of solution.

In an embodiment, the active means of controlling the temperature of the photovoltaic module 104 can be implemented. For instance, the temperature of the photovoltaic module 104 can be monitored via one or more sensors adjacent to, incorporated into, or attached to, the photovoltaic module 104. A temperature sensor could also be adjacent to, incorporated into, or attached to the thermal energy absorption enclosure 106.

Although the thermal energy absorption enclosure 106 is described in the singular, two or more thermal energy absorbing cavities 106 can also be implemented.

Thermally connected, or a thermal connection, or a conductive thermal connection can include any connection through a medium having a thermal conductivity similar to or greater than thermal conductors such as steel, copper, silver, thermal paste, diamond, to name a few. Thermally connected, or a thermal connection, or a conductive thermal connection do not include connections through a medium having a thermal conductivity similar to thermal insulators such as atmospheric air, polymers, polystyrene, silica aerogel, xenon, wood, rubber, cement, to name a few.

FIG. 1b illustrates an embodiment of the photovoltaic cogeneration unit 110 illustrated in FIG. 1. The photovoltaic cogeneration unit 110 includes the photovoltaic module 104, the thermal energy absorption enclosure 106, and a heating fluid 108. The photovoltaic module 104 can generate thermal energy. The thermal energy absorption enclosure 106 can be in contact with or be a part of the photovoltaic module 104. The thermal energy absorption enclosure 106 can remove a portion of the thermal energy from the photovoltaic module 104. The heating fluid 108 can pass through the thermal energy absorption enclosure 106 (either clockwise or counterclockwise despite the arrows in the illustrated embodiment). While passing through the thermal energy absorption enclosure 106 the heating fluid 108 can absorb the portion of the thermal energy and remove the portion of the thermal energy from the thermal energy absorption enclosure 106.

The photovoltaic cogeneration unit 110 can also include at least two heating fluid input/output conduits 140, 150. At least one heating fluid input/output conduit 140, 150 can be configured to transport the heating fluid 108 at a first temperature into the thermal energy absorption enclosure 106. At least one heating fluid input/output conduit 140, 150 can be configured to transport the heating fluid 108 at a second temperature out of the thermal energy absorption enclosure 106. The second temperature can be higher than the first temperature since the heating fluid 108 absorbs a portion of the thermal energy from the photovoltaic module 104 as the heating fluid 108 passes through the thermal energy absorption enclosure 106. The illustrated embodiment uses arrows to indicate one direction that heating fluid 108 could travel while passing through the thermal energy absorption enclosure 106. However, it should be understood that this is illustrative only, and that other directions of heating fluid 108 travel as well as other numbers and configurations of the heating fluid input/output conduits 140, 150 is also possible.

In an embodiment, the thermal energy absorption enclosure 106 or the heating fluid input/output conduits 140, 150 can be used to provide thermal energy. For instance, they could be used to melt snow or ice on the photovoltaic module 104. They could also be used to provide direct thermal energy to a structure, object, or space. These embodiments can be controlled by a controller that both monitors temperatures and determines when thermal energy is to be released into the structure, object, or space.

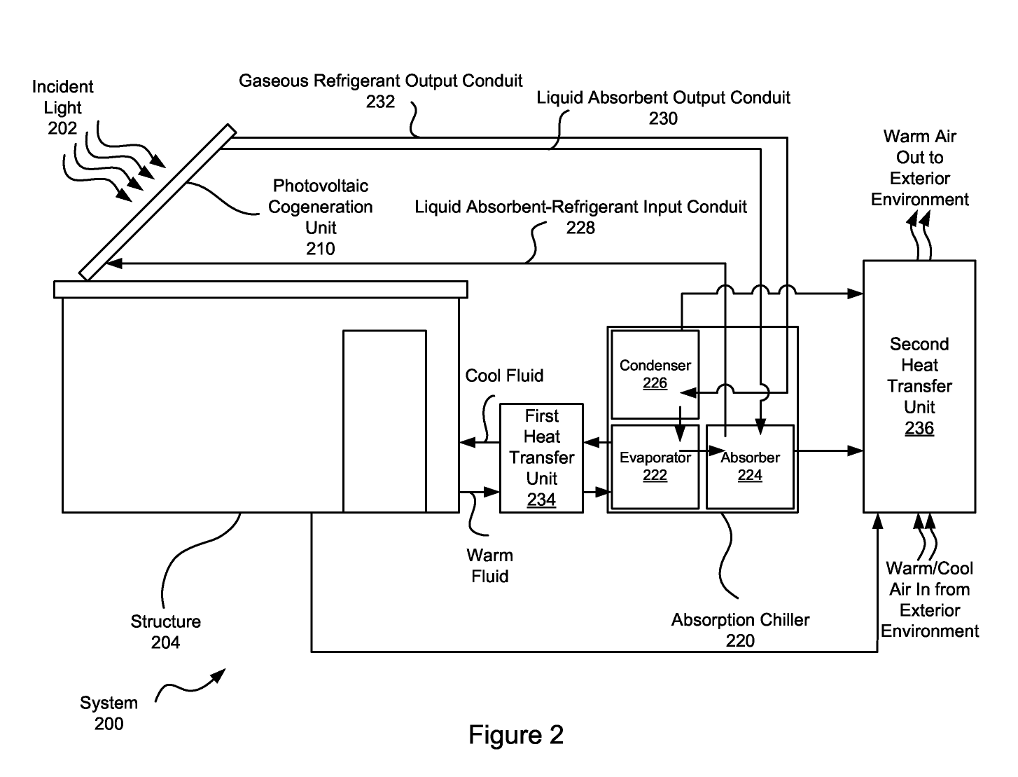

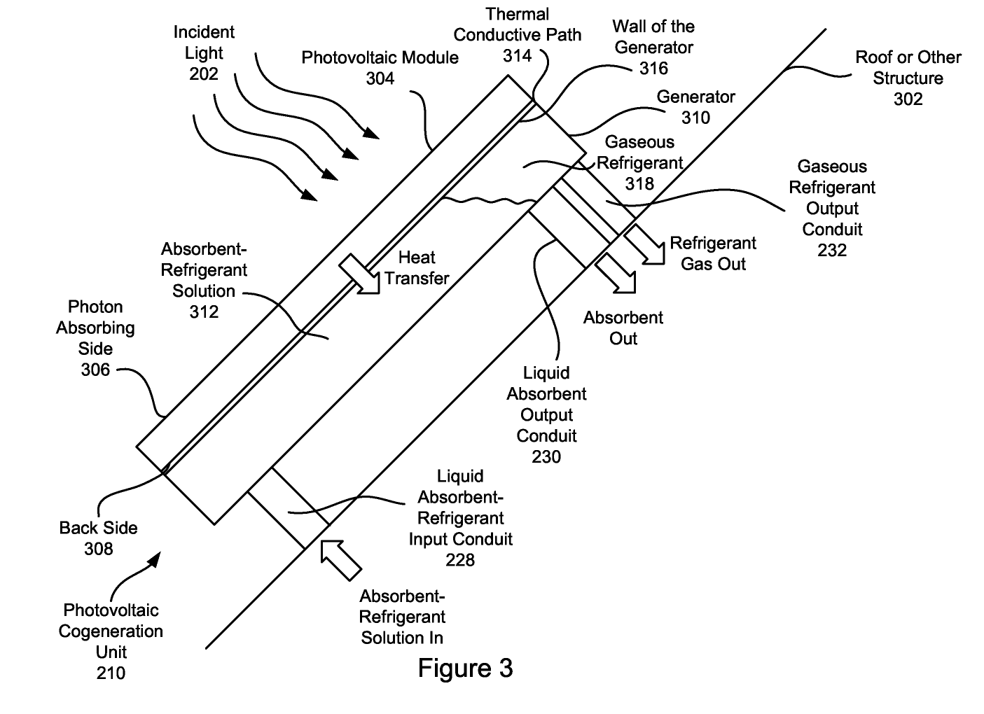

FIG. 2 illustrates a system 200 including an absorption chiller 220 having a generator that is heated via thermal energy drawn from a photovoltaic module. The photovoltaic module (see FIG. 3) is part of a photovoltaic cogeneration unit 210. The photovoltaic module absorbs incident light 202 and generates electricity and excess thermal energy. The photovoltaic module is thermally connected to a generator (see FIG. 3) of the absorption chiller 220. The generator removes thermal energy from the photovoltaic module and uses the thermal energy as an energy input to run the absorption chiller 220. By removing thermal energy from the photovoltaic module, the solar cells within the photovoltaic module are cooled, which allows the solar cells to run more efficiently. The system 200 is thus able to generate electricity more efficiently than if a non-cooled photovoltaic module was used, and able to generate cool air to cool a structure 204 (or other entity requiring cooling) without using electricity.

The absorption chiller 220 includes an evaporator 222, an absorber 224, the generator, and a condenser 226. In an embodiment, the evaporator 222 removes heat from the structure 204 and transfers the heat into the refrigerant. The refrigerant starts in a liquid state, but the heat from the structure 204 causes the liquid refrigerant to evaporate or boil. Once converted to a gaseous state, the refrigerant is transferred to the absorber 224 where it is absorbed into the absorbent to form a liquid absorbent-refrigerant solution. The liquid absorbent-refrigerant solution is a liquid in which the refrigerant gas has been absorbed into the liquid absorbent. The liquid absorbent-refrigerant solution is then transferred to the generator via a liquid absorbent-refrigerant input conduit 228. The generator uses thermal energy from the photovoltaic module to boil the absorbent-refrigerant solution and thereby separate the refrigerant and absorbent. Since the refrigerant has a lower boiling point than the absorbent, the refrigerant boils while the absorbent remains primarily liquefied (some absorbent adheres to the vaporizing refrigerant and the combination forms gas-filled bubbles). The liquid absorbent is then transferred back to the absorber 224 via a liquid absorbent output conduit 230. The refrigerant, now in a gaseous state and called a gaseous refrigerant, is transferred to the condenser 226 via a gaseous refrigerant output conduit 232. The condenser 226 removes heat from the gaseous refrigerant (e.g., via a heat exchanger) causing the gaseous refrigerant to condense into a liquid refrigerant. The liquid refrigerant can be transferred back to the evaporator 222 where the cycle begins anew.

The absorption chiller 220 uses thermal energy instead of mechanical energy (e.g., a compressor) to cool the structure 204, a space, or an object. In an embodiment, the absorption chiller 220 includes an absorbent and a refrigerant. Examples of absorbent-refrigerant combinations include water and liquid ammonia, and Lithium Bromide (LiBr) and water. An absorbent can extract one or more substances from a fluid (gas or liquid) medium on contact. In the process, the absorbent generally undergoes a physical and/or chemical change. A refrigerant is used to provide cooling in the absorption chiller 220. The refrigerant absorbs thermal energy during a gas to liquid phase transformation in the evaporator 222. The refrigerant releases thermal energy during a gas to liquid phase transformation in the condenser 226.

While the absorption chiller 220 has been described as having four distinct chambers or compartments (i.e., the evaporator 222, the absorber 224, the generator, and the condenser 226), it should be understood that any one or more of these compartments can reside within the same chamber or compartment. For example, the evaporator 222 and the absorber 224 can be within the same chamber. In such an embodiment, the evaporator 222 can include a series of meandering pipes, or a heat exchanger, used to cool warm air from the structure 204. The absorber 224 can comprise a pool of absorbent residing in the same chamber as the meandering pipes that make up the evaporator 222. The refrigerant could be dripped or sprayed onto the heat exchanger causing the refrigerant to boil, and the gaseous refrigerant could diffuse through the chamber and come into contact with and be absorbed by the pool of absorbent. This is a non-limiting example solely intended to show that one or more of the evaporator 222, the absorber 224, the generator, and the condenser 226 can exist in a single compartment or chamber.

In the illustrated embodiment, the absorption chiller 220 is distributed between two locations: a location adjacent to and level with the structure 204, and a location within the photovoltaic cogeneration unit 210. In other words, the generator and the rest of the absorption chiller 220 are in different locations. In another embodiment of the absorption chiller 220, the evaporator 222, absorber 224, generator, and condenser 226 can be in the same location. For instance, all four components can be located atop or affixed to the structure 204. Alternatively, two or more of the four components of the absorption chiller 220 can be distributed in separate locations.

The evaporator 222 is configured to remove heat from the structure 204. Thermal energy can also be removed from any structure, space, object, or other entity where there is a need to remove thermal energy or for cooling. The evaporator 222 can remove thermal energy from two or more structures, spaces, objects, or other entities. In an embodiment, the evaporator 222 is thermally connected to a first heat transfer unit 234. The first heat transfer unit 234 can include heat pumps, fans, and/or other means for moving thermal energy and/or air. In an embodiment, the first heat transfer unit 234 is configured to transport cool fluid (liquid or gas) from the evaporator 222 to the structure 204, and to transport warm fluid from the structure 204 to the evaporator 222. The second heat transfer unit 234 is illustrated as being located adjacent to and level with the structure 204 and a portion of the absorption chiller 220. However, this configuration is illustrative only. The first heat transfer unit 234 can be located in a variety of locations as long as it is able to transfer fluids between the evaporator 222 and the structure 204.

To bring warm fluid into the evaporator 222 and to send cold fluid out, the evaporator 222 can include a heat exchanger. A heat exchanger is a device that transfers thermal energy from one fluid to another fluid without allowing the fluids to touch or mix. For instance, the heat exchanger can include a series of meandering conduits that allow a fluid to pass through the evaporator 222 and transfer thermal energy into the evaporator 222. Other types of heat exchangers can also be used.

Sometimes the generator of the absorption chiller 220 does not sufficiently separate the absorbent and refrigerant. Specifically, the refrigerant can be boiled out of the absorbent, but some absorbent may form bubbles around the gaseous refrigerant. To provide further separation, the absorption chiller 220, in an embodiment, includes one or more curving conduits between the generator and the condenser 226. As the bubbles run into the walls of the curving conduit, the bubbles pop. The gaseous refrigerant continues to rise through the meandering conduit while the liquid absorbent returns to the generator via the force of gravity. By the time the gaseous refrigerant reaches the condenser 226, the gaseous refrigerant is nearly pure or completely pure (free from absorbent).

In an embodiment, the absorption chiller 220 uses a continuous absorption cycle. In another embodiment, the absorption chiller 220 uses an intermittent absorption cycle.

The absorption chiller 220 includes an absorber 224. The absorber is configured to enable the absorbent to absorb the refrigerant. When the absorbent absorbs the refrigerant, a first amount of thermal energy is released. The first amount of thermal energy can be released into an external environment—the air surrounding the system 200. In an embodiment, a second heat transfer unit 236 can remove the first amount of thermal energy from the absorber 224 and release the first amount of thermal energy into the external environment. The second heat transfer unit 236 can be a cooling tower or any other device configured to release thermal energy into the external environment. In an embodiment, the second heat transfer unit 236 is optionally configured to remove thermal energy from the structure 204. In this embodiment, the second heat transfer unit 236 can be an air conditioning unit, a heat pump, a cooling tower, or any other device configured to remove thermal energy from the structure 204. The second heat transfer unit 236 is illustrated as being located adjacent to and level with the absorption chiller 220. However, this configuration is illustrative only. The second heat transfer unit 236 can be located in a variety of locations as long as it is able to transfer fluids and thermal energy between the absorption chiller 220 and the external environment.

Once the gaseous refrigerant from the evaporator 222 has been absorbed in the absorber 224 to form the absorbent-refrigerant solution, the absorbent-refrigerant solution can be transported to the generator via a liquid absorbent-refrigerant conduit 228. The liquid absorbent-refrigerant conduit 228 and the generator will be discussed further in the discussion of FIG. 3. The generator splits the absorbent and refrigerant and transports the gaseous refrigerant to the condenser 226 via a gaseous refrigerant output conduit 232. The liquid absorbent is transported back to the absorber 224 via a liquid absorbent output conduit 230. The liquid absorbent recombines with the liquid absorbent in the absorber 224 and is again used to absorb more gaseous refrigerant from the evaporator 222.

The gaseous refrigerant that is transported from the generator to the condenser 226 is condensed in the condenser 226 by removing a second amount of thermal energy from the gaseous refrigerant. The second amount of thermal energy can be released into the external environment. In an embodiment, the second heat transfer unit 236 removes the second amount of thermal energy from the condenser 226 and releases the second amount of thermal energy into the external environment.

FIG. 3 is a detail view of an embodiment of the photovoltaic cogeneration unit illustrated in FIG. 2. The photovoltaic cogeneration unit 210 can be fixed to a roof or other structure 302. The photovoltaic cogeneration unit 210 includes a photovoltaic module 304. The photovoltaic module 304 has one or more photovoltaic cells connected in series, in parallel, or in a combination of series and parallel. The photovoltaic cells are configured to absorb the incident light 202 and convert the sun's energy into electricity. Absorption takes place via a photon absorbing side 306 of the photovoltaic module 304. While some of the incident light 202 is converted to free carriers in the semiconductor of the solar cells some of the incident light 202 is absorbed by the photovoltaic module 304 and converted to thermal energy. This heat or thermal energy, can be removed from the photovoltaic module 304 via the back side 308 of the photovoltaic module 304.

The thermal energy can pass through a thermal conductive path 314 and enter the generator 310 (the same generator previously referred to in FIG. 2). The thermal conductive path 314 can create a thermal connection between the back side 308 and a wall of the generator 316. The thermal conductive path 314 enables a first amount of thermal energy to be transferred from the back side 308 to the generator 310 and into an absorbent-refrigerant solution 312. The absorbent-refrigerant solution 312 enters the generator 310 from the absorber 224 via the liquid absorbent-refrigerant input conduit 228. As heat is transferred into the absorbent-refrigerant solution 312, the temperature of the absorbent-refrigerant solution 312 rises. When the temperature of the absorbent-refrigerant solution 312 reaches a refrigerant boiling temperature (dependent upon the partial pressure within the generator 310), the refrigerant begins to transform from a liquid to a vapor, or a gaseous refrigerant 318. Still liquefied and now largely free from refrigerant, a liquid absorbent can be transported back to the absorber 224 via a liquid absorbent output conduit 230. The liquid absorbent is then reused by the absorber 224 to absorb newly evaporated refrigerant from the evaporator 222. The gaseous refrigerant 318 can be transported from the generator 310 to the condenser 226 via a gaseous refrigerant output conduit 232. In the condenser 226, thermal energy is removed from the gaseous refrigerant causing it to condense into a liquid refrigerant. At this point the liquid refrigerant is free from substantially all other substances (mainly absorbent) and can be transported to the evaporator 222 to begin the absorption cooling cycle again.

Thermal energy and heat are used interchangeably in this disclosure. Thermal energy includes sensible energy and latent energy in a system. Sensible energy is the portion of internal energy associated with kinetic energies including molecular/atomic translation, molecular/atomic rotation, molecular/atomic vibration, electron translation, electron spin and nuclear spin. Latent energy includes the internal energy associated with the phase of a system.

The photovoltaic cogeneration unit 210 can be mounted flush (not illustrated) with the roof or other structure 302 or can be mounted on a supporting system/device in order to provide an air gap (as illustrated) between the photovoltaic cogeneration unit 210 and the roof or other structure 302. The photovoltaic cogeneration unit 210 can be parallel with the roof or other structure 302 or can be mounted at an angle to the roof or other structure 302. The photovoltaic cogeneration unit 210 can be mounted so as to face a part of the sky where the photovoltaic cells can absorb the most incident light 202. In an embodiment, the photovoltaic cogeneration unit 210 can be movable relative to the roof or other structure 302 in order to allow tracking of the sun. In an embodiment, the photovoltaic module 304 can be movable to allow tracking of the sun, while the generator 310 can be fixed relative to the roof or other structure 302.

The photovoltaic module 304 includes photovoltaic cells (or solar cells) and structural components to support and protect the photovoltaic cells and accompanying electronics. All of these components absorb some of the incident light 202 and convert the incident light 202 to thermal energy. The thermal energy, whether in the photovoltaic cells, or transferred into the photovoltaic cells from hotter portions of the photovoltaic module 304, can decrease the efficiency of the photovoltaic cells.

The photovoltaic module 304 includes a photon absorbing side 306. The photon absorbing side 306 is the side or surface of the photovoltaic module 304 that faces the incident light 202. The photovoltaic module 304 also includes the back side 308. The back side 308 can be the surface of the photovoltaic module 304 that is opposite the incident light 202. In an embodiment, the back side 308 is configured to support and protect the photovoltaic cells and accompanying electronics while at the same time is configured to allow a high rate of thermal energy transfer out of the photovoltaic module 304. Hence, the back side 308 can also be made of a material that has high thermal conductivity. In an alternative embodiment, the back side 308 can be made of materials having high thermal conductivity and materials having low thermal conductivity.

The third amount of thermal energy can travel from the back side 308 to the generator 310 via the thermal conductive path 314. In an embodiment, the thermal conductive path 314 transfers the third amount of thermal energy via conduction—the transfer of thermal energy via the contact of atoms and molecules. In an embodiment, the thermal conductive path 314 transfers the third amount of thermal energy via convection—the transfer of thermal energy via the movement of atoms and molecules. In an embodiment, the thermal conductive path 316 transfers the third amount of thermal energy via radiation—the transfer of thermal energy via photons. In an embodiment, the thermal conductive path 314 transfers the third amount of thermal energy via two or more of the following: conduction, convention, or radiation. In an embodiment, the thermal conductive path 314 is a material having high thermal conductivity (e.g., thermal grease, thermal compound, thermal paste, heat paste, heat sink paste, heat transfer compound, or heat sink compound, to name a few). For instance, the thermal conductive path 314 can be thermal grease applied between the back side 308 and the generator 316. In an embodiment, the thermal conductive path 314 is a material or substance so thin that the material does not hinder heat transfer. In other words the material or substance is so thin that it is a poor thermal insulator.

In an embodiment, the thermal conductive path 314 includes a wall of the generator 316. The wall of the generator 316 is adjacent to the back side 308 and in contact with the thermal conductive path 314. The wall of the generator 316 can be made from a material or combination of materials that do not interact with or corrode upon contact with the absorbent-refrigerant solution, the pure refrigerant (in a liquid or vapor state), or the pure absorbent (in a liquid or vapor state). In an embodiment, the back side 308 connects directly to the wall of the generator 316 and there is no thermal conductive path 314. In other words, the generator 310 and the photovoltaic module 304 can be in direct contact.

Although FIG. 3 illustrates an embodiment where the wall of the generator 316 is flat and the back side 308 of the photovoltaic module 304 is flat, other shapes and configurations are also possible. Alternative shapes and configurations can decrease the distance that thermal energy must travel between the photovoltaic module 304 and the wall of the generator 316. Alternative shapes and configurations can decrease the thickness of material that thermal energy must travel through to reach the wall of the generator 316. Alternative shapes and configurations can increase the surface area of the wall of the generator 316 in order to increase the rate at which the generator 310 can absorb thermal energy. Other shapes and configurations commonly used in the field of heat transfer can also be implemented without departing from the spirit of the disclosure. The square or rectangular profile of the generator 310 illustrated in FIG. 3 is illustrative only. One skilled in the art will recognize that the generator 310 can take on other shapes and configurations without departing from the spirit of the disclosure.

The three conduits 228, 230, 232 can be hollow and tubular in shape, although other shapes can also be used. The conduits can be flexible, rigid, or a combination of the two. The locations and configurations of the three conduits 228, 230, 232 in FIG. 3 are illustrative only. One skilled in the art will recognize that the conduits 228, 230, 232 can have a variety of locations and configurations.

When the refrigerant boils out of the absorbent-refrigerant solution 312, a portion of the absorbent, in liquid form, can form bubbles around the gaseous refrigerant 318. Therefore, the system 200 may include a means for separating the liquid absorbent from the gaseous refrigerant 318. In an embodiment, after the gaseous refrigerant 318, inside liquid absorbent bubbles, leaves the generator 310, but before it reaches the condenser 226, the bubbles can pass through one or more meandering (or twisting or curved or non-straight or non-linear) conduits such that the bubbles impact the sides of the meandering conduits and break. The gaseous refrigerant 318, now pure and free from absorbent, continues to rise towards the condenser 226 while the now pure liquid absorbent drips back to the absorber 224 via the force of gravity. Thus, passing the bubbles through the meandering conduits on the way to the condenser 226 completes the process of separating the refrigerant from the absorbent.

Returning to the generator 310, the ratio of absorbent to refrigerant in the absorbent-refrigerant solution 312 can vary or have a gradient. The absorbent-refrigerant solution 312 near a top surface of the absorbent-refrigerant solution 312 can have the smallest concentration of refrigerant. This portion can be transported back to the absorber 224 via liquid absorbent output conduit 232. In an embodiment, the liquid absorbent output conduit 232 transports pure liquid absorbent to the absorber 236. In other embodiment, a small amount of refrigerant remains in solution and is transported back to the absorber 224 along with the liquid absorbent.

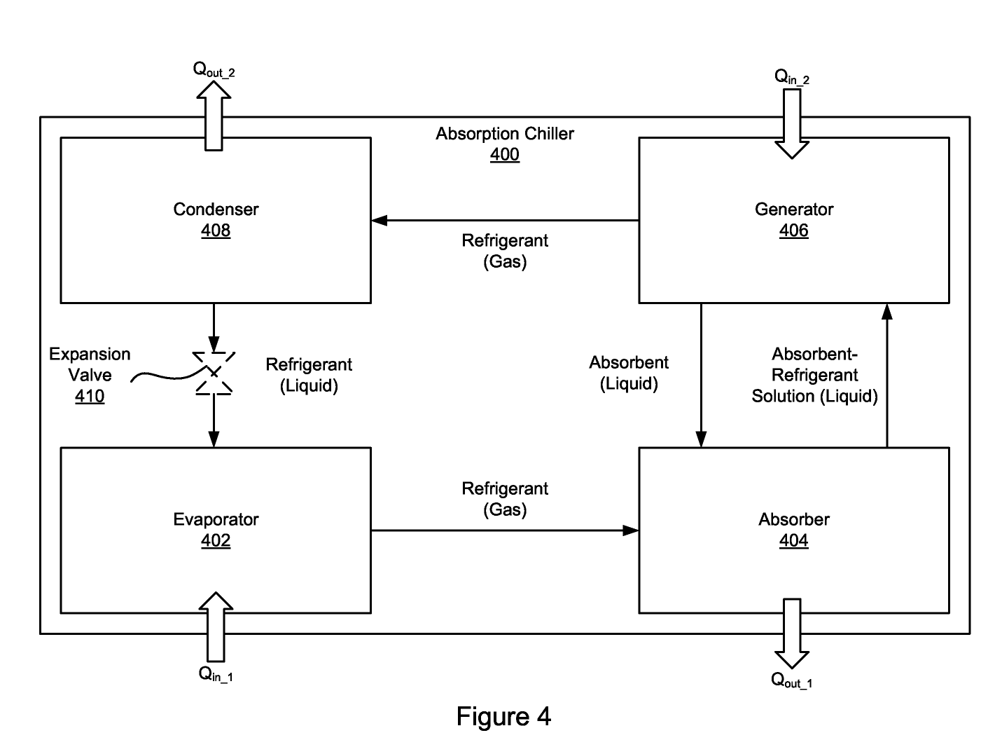

FIG. 4 illustrates one embodiment of an absorption chiller 400. Absorption cooling is a process in which cooling of a space, structure, or object is accomplished by the evaporation of a volatile fluid (a refrigerant), which is then absorbed in a solution (an absorbent), then desorbed or boiled using thermal energy from a heat source (e.g., turbine exhaust, excess heat from photovoltaic modules), and then condensed. The refrigerant can be one that evaporates at room temperature such as Lithium Bromide (LiBr). Two common absorbent-refrigerant combinations are LiBr-water, and water-ammonia.

The absorption chiller 400 includes an evaporator 402 for cooling a space, structure or object. The absorption chiller 400 includes an absorber 404 where the refrigerant dissolves or is absorbed into the absorbent. The absorption chiller 400 includes a generator 406 for boiling the absorbent-refrigerant solution. In the generator 406, the refrigerant turns into a gas that is primarily devoid of absorbent. However, some absorbent may remain in the form of bubbles that enclose the gaseous refrigerant. The absorption chiller 400 can therefore include a separator (not illustrated) for breaking these bubbles and completing the separation of the gaseous refrigerant from the liquid absorbent. The gaseous refrigerant is then transported to a condenser 408 where heat is removed from the gaseous refrigerant causing the gaseous refrigerant to liquefy. The liquid refrigerant is then transported to the evaporator 402 where the cycle begins again. In an embodiment, the absorption chiller 400 optionally includes an expansion valve 410 that allows the liquid refrigerant to be released back into the evaporator 402 at lower pressure.

The absorption cooling cycle begins with the refrigerant in a liquid state evaporating in the evaporator 402. When the liquid refrigerant boils, this phase change removes a first amount of thermal energy Qᵢₙ_{_{—}}₁ from the space, structure, or object that the absorption chiller 400 is intended to cool. This can be done via the use of a heat exchanger located inside or adjacent to the evaporator 402. Cooling pipes snaking through the evaporator 402 are one example of a heat exchanger.

The gaseous refrigerant is then absorbed in an absorbent at the absorber 404. The refrigerant has a high affinity for the absorbent. Affinity is the probability of a chemical dissolving into another chemical. As such, when the refrigerant, in a gaseous state, comes into contact with the absorbent, in a liquid state, the refrigerant is absorbed into the absorbent. The resulting solution is called a liquid absorbent-refrigerant solution. This absorption process releases a second amount of thermal energy Qₒᵤₜ_{_{—}}₁ that can be released into an external environment, for instance via a cooling tower.

The liquid absorbent-refrigerant solution generally will not boil at a low enough temperature to be useful for cooling. Thus, the two chemicals are separated in the generator 406. A third amount of thermal energy Qᵢₙ_{_{—}}₂ is added to the liquid absorbent-refrigerant solution. Since the refrigerant has a lower boiling temperature than the absorbent, the refrigerant escapes from the absorbent as a gas. The third amount of thermal energy Qᵢₙ_{_{—}}₂ can be provided by a variety of sources or multiple sources. Some examples include excess hot water or steam from an industrial plant, hot water heated by the sun, or as this disclosure describes, heat removed from solar cells.

The gaseous refrigerant rises in bubbles formed from a small amount of absorbent. To complete the separation of refrigerant and absorbent, the rising bubbles pass through a series of twisting conduits causing the bubbles to impact the conduits' sides and break the bubbles. As a result the absorbent trickles down the conduits and is returned to the absorber 404. The gaseous refrigerant continues to rise through the twisting conduits. The twisting conduits can be referred to as a separator (not illustrated).

Now that the gaseous refrigerant has been purified (or substantially purified), the gaseous refrigerant is condensed in the condenser 408. This is done by removing a fourth amount of thermal energy Qₒᵤₜ_{_{—}}₂. The fourth amount of thermal energy can be removed via a heat exchanger. The fourth amount of thermal energy Qₒᵤₜ_{_{—}}₂ can be released into an external environment, for instance via a cooling tower. The liquid refrigerant is then ready to be fed into the evaporator 402 again.

Substituting thermal energy for mechanical compression means that absorption chillers can use much less electricity than mechanical compressor chillers. Absorption chillers can be cost-effective when the thermal energy they consume is less expensive than the electricity that is displaced.

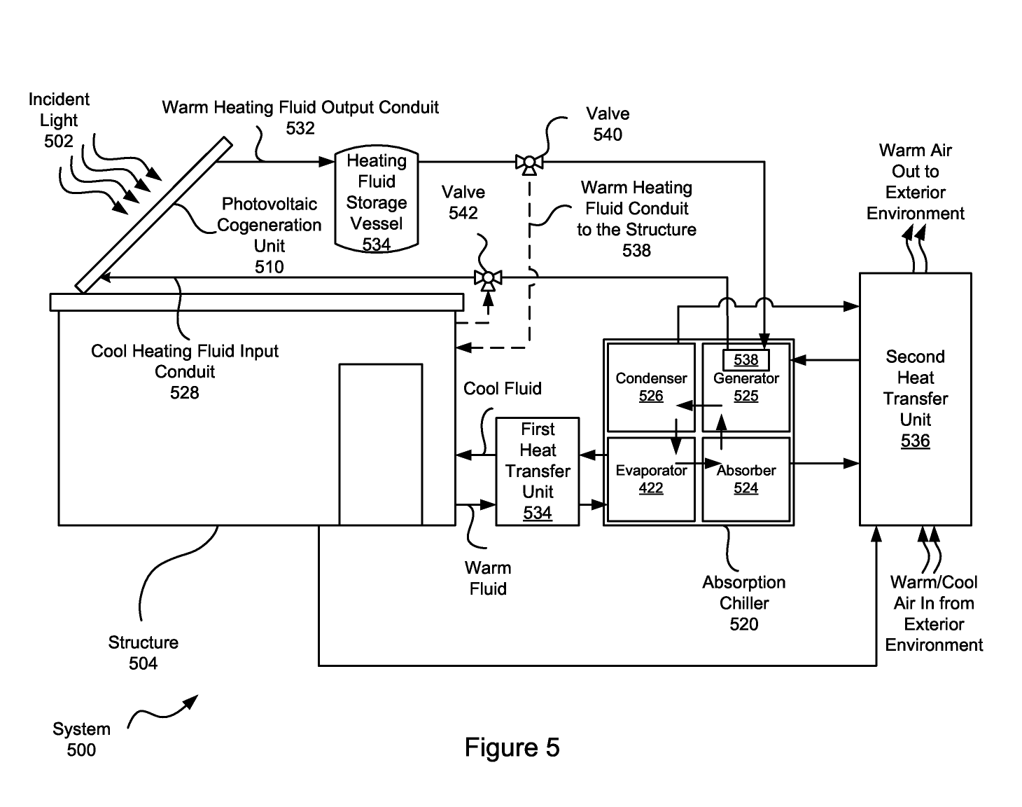

FIG. 5 illustrates a system 500 including an absorption chiller located adjacent to a structure 504, and having a thermal energy input provided by a heating fluid that is heated via a photovoltaic cogeneration unit 510. The system 500 is similar to the system 200 discussed with reference to FIGS. 2-3 in that excess thermal energy is removed from a photovoltaic module in order to cool the photovoltaic module and drive an absorption chiller 520. However, since the absorbent, refrigerant, and possibly other chemicals in an absorption chiller 520 can be harmful or dangerous to humans and the structure 504, the system 500 utilizes an absorption chiller that is entirely separate from the structure 504 and incapable of spilling onto the structure 504. Rather than transferring thermal energy directly from the photovoltaic module to the generator as described with reference to FIGS. 2-3, the system 500 absorbs thermal energy from the photovoltaic module in a heating fluid (e.g., water) and transports the heating fluid to the absorption chiller 520 where the thermal energy is conveyed to the generator 525. Heating fluid is any liquid or gas having a high heat capacity, posing little danger to humans, and possessing low corrosive characteristics.

System 500 includes an absorption chiller 520 having an evaporator 522, an absorber 524, a generator 525, and a condenser 526. In an embodiment, the absorption chiller 520 can use water as a refrigerant and lithium bromide as an absorbent. The evaporator 522 removes heat from the structure 504, space, object, or other entity requiring cooling. The thermal energy input for the generator 525 is provided by excess thermal energy absorbed in a photovoltaic module of a photovoltaic cogeneration unit 510. Excess thermal energy in the photovoltaic module is absorbed in a heating fluid converting cool heating fluid into warm heating fluid. Cool heating fluid is a fluid (gas or liquid) having a lower temperature than the temperature of the photovoltaic module, and thus able to absorb thermal energy from the photovoltaic module. Warm heating fluid is a fluid having a higher temperature than the cool heating fluid. The warm heating fluid is transported to the absorption chiller 520 via a warm heating fluid output conduit 532. The thermal energy in the warm heating fluid is conveyed to the generator 525 via a heat exchanger 538. The warm heating fluid output conduit 532 is connected between the photovoltaic cogeneration unit 510 and the heat exchanger 538 of the generator 510. In an embodiment, the warm heating fluid (or a portion of the thermal energy) can be stored in a heating fluid storage vessel 534, stored there temporarily, and then transported to the absorption chiller 520. In transferring thermal energy to the generator 525, the warm heating fluid changes to cool heating fluid. The cool heating fluid can be transported back to photovoltaic cogeneration unit 510 via cool heating fluid input conduit 528. The cool heating fluid input conduit 528 is connected between the photovoltaic cogeneration unit 510 and the heat exchanger 538 of the generator 510. The cool heating fluid is then used to remove more thermal energy from the photovoltaic module.

The absorption chiller 520 need not always be located as illustrated in FIG. 5. Rather the absorption chiller 520 can be located anywhere that does not pose a risk to humans or the structure 504 should chemicals in the absorption chiller 520 escape or leak. Similarly, while the illustrated absorption chiller 520 is not distributed amongst different locations (compare to the absorption chiller 220 in FIG. 2), were any one or more of the evaporator 522, absorber 524, generator 525, or condenser 526 distributed, they should be so distributed as to avoid endangering humans or the integrity of the structure 504 should the absorption chiller 520 leak.

To facilitate thermal energy transfer from the heating fluid to the generator 525, the system 500 can include a heat exchanger 538. The heat exchanger 538 can be connected to, or have a thermal connection to, the generator 525. The heat exchanger 538 can convert the warm heating fluid to a cool heating fluid by transferring a second amount of thermal energy from the warm heating fluid to the generator 525. The heat exchanger can reside within the generator 525, connect to the generator 525, or reside partially inside and partially outside the generator 525.

The evaporator 522 is configured to remove thermal energy from the structure 504. Thermal energy can also be removed from any structure, space, object, or other entity where there is a need to remove thermal energy or for cooling. The evaporator 522 can remove thermal energy from two or more structures, spaces, objects, or other entities. In an embodiment, the evaporator 522 is thermally connected to a first heat transfer unit 534. The first heat transfer unit 534 can include heat pumps, fans, and/or other means for moving thermal energy and/or air. In an embodiment, the first heat transfer unit 534 is configured to transport cool fluid (liquid or gas) from the evaporator 522 to the structure 504, and to transport warm fluid from the structure 504 to the evaporator 522. The first heat transfer unit 534 is illustrated as being located adjacent to and level with the structure 504 and a portion of the absorption chiller 520. However, this configuration is illustrative only. The first heat transfer unit 534 can be located in a variety of locations as long as the first heat transfer unit 534 is able to transfer fluids between the evaporator 522 and the structure 504.

The heating fluid storage vessel 534 is located between the photovoltaic cogeneration unit 510 and the absorption chiller 520. In an embodiment, the heating fluid storage vessel 534 is located atop the structure 504. In an embodiment, the heating fluid storage vessel 534 is located adjacent to the structure 504, not atop the structure 504. In an embodiment, the heating fluid storage vessel 534 is located adjacent to the absorption chiller 520. While the heating storage vessel 534 is illustrated as only being connected to the warm heating fluid output conduit 532, in an embodiment, the heating storage vessel 534 can also be connected to the cool heating fluid input conduit 528. In an embodiment, the heating storage vessel 534 can be a low-temperature heating storage vessel. A low-temperature heating storage vessel is a vessel having a fluid that is at a lower temperature than a temperature of the photovoltaic module. The heating storage vessel 534 need not be enclosed on at least six sides. For instance, a swimming pool is a non-limiting example of a heating storage vessel 534.

The system 500 can also include a second heat transfer unit 536. In an embodiment, the second heat transfer unit 536 can remove thermal energy from the absorber 524 and release the thermal energy into an external environment. In an embodiment, the second heat transfer unit 536 can remove thermal energy from the condenser 526 and release the thermal energy into the external environment. In an embodiment, the second heat transfer unit 536 can remove thermal energy from the structure 504 and release the thermal energy into the external environment. In an embodiment, the second heat transfer unit 536 can remove thermal energy from the external environment and transport it to the generator 525. For instance, the second heat transfer unit 536 can include a solar thermal collector to collect thermal energy in a heating fluid and transfer the thermal energy to the generator 525 via movement of the heating fluid. The purpose of such thermal energy transfer is to supplement the thermal energy removed from the photovoltaic module.

In addition to using thermal energy removed from the photovoltaic module to heat the generator 525, the thermal energy can also be used to heat rather than cool the structure 504. To accomplish this, in an embodiment, the system 500 optionally includes a warm heating fluid conduit to the structure 538 for transferring all or a portion of the warm heating fluid in the warm heating fluid output conduit 532 into the structure 504. The system 500 can include a first valve 540 to controllably direct warm heating fluid to the generator 525 or to the structure 504. In an embodiment, the first valve 540 can be a two-way valve. Cool fluid can be directed back to the photovoltaic cogeneration unit 510, from the structure 504, via a return conduit that can connect with a second valve 542. In an embodiment, the second valve 542 can be a two-way valve.

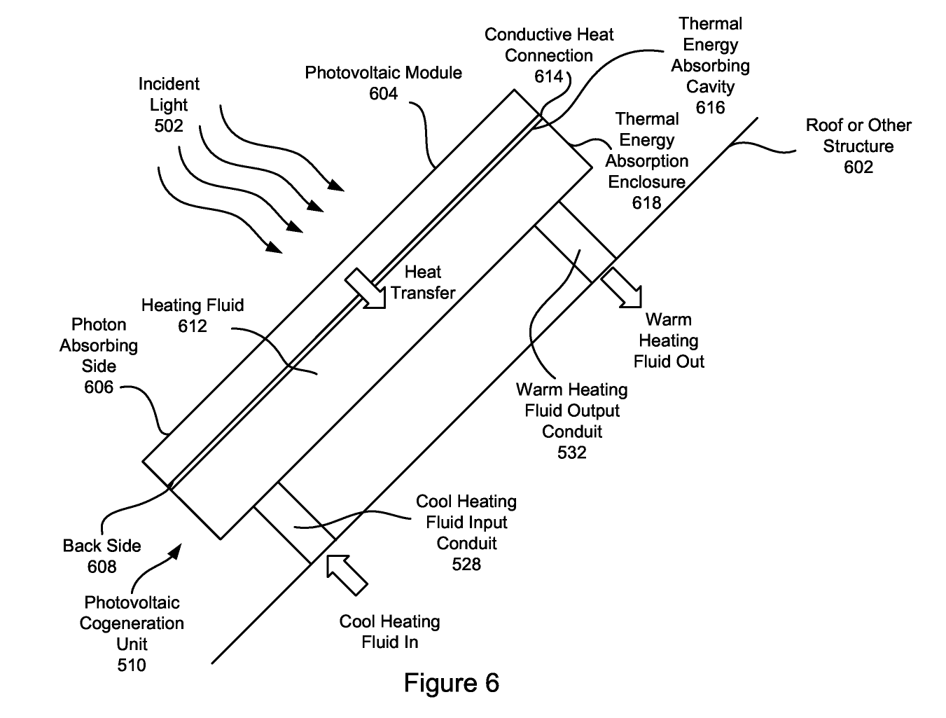

FIG. 6 is a detailed embodiment of the photovoltaic cogeneration unit 510 illustrated in FIG. 5. The photovoltaic cogeneration unit 510 can be fixed to a roof or other structure 602. The photovoltaic cogeneration unit 510 includes a photovoltaic module 604. The photovoltaic module 604 has one or more photovoltaic cells connected in series, in parallel, or in a combination of series and parallel. The photovoltaic cells are configured to absorb the incident light 502 and convert the sun's energy into electricity. Absorption takes place via a photon absorbing side 606 of the photovoltaic module 604. While some of the incident light 502 is converted to free carriers in the semiconductor of the solar cells some of the incident light 502 is absorbed by the photovoltaic module and converted to thermal energy. This heat or thermal energy, can be removed from the photovoltaic module 604 via the back side 608 of the photovoltaic module 604.

The thermal energy can pass through a conductive heat connection 614 and can enter the thermal energy absorption enclosure 618. The conductive heat connection 614 allows the thermal energy absorption enclosure 618 to be thermally connected to the back side 608 of the photovoltaic module 604. More particularly, the conductive heat connection 614 creates a conductive thermal connection between the back side 608 and a wall of the thermal energy absorption enclosure 616. The conductive heat connection 614 enables a third amount of thermal energy to be transferred from the back side 608 to the thermal energy absorption enclosure 618 and into the heating fluid 612. The heating fluid 612 enters the thermal energy absorption enclosure 618 as cool heating fluid from the absorber 524 via the cool heating fluid input conduit 528. As the third amount of thermal energy is transferred into the heating fluid 612, the temperature of the heating fluid 612 rises, and the cool heating fluid is converted to warm heating fluid. This warm heating fluid is then transported to the generator 525 via warm heating fluid output conduit 532 (and optionally being temporarily stored in the heating fluid storage vessel 534).

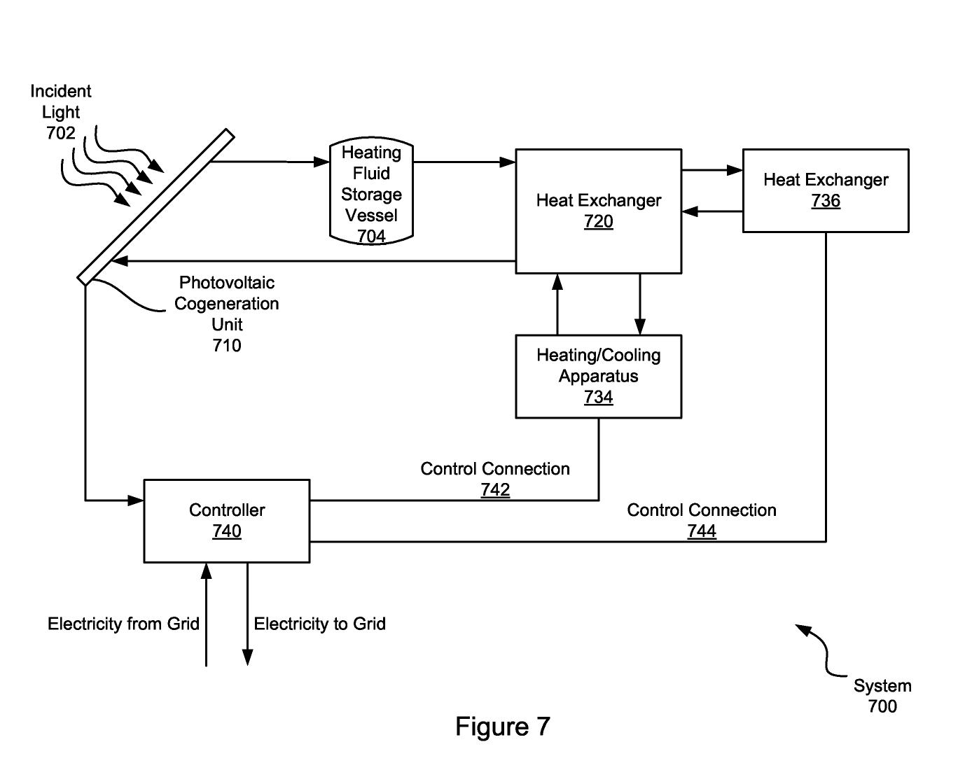

FIG. 7 illustrates an embodiment of a system 700 for cooling a photovoltaic module. System 700 includes a photovoltaic cogeneration unit 710 that includes a photovoltaic module. The photovoltaic module converts incident light 702 into electricity. The photovoltaic module also generates heat or thermal energy from absorbed light that is not converted into electricity. This thermal energy can be removed, and thus improve the photovoltaic module efficiency, by removing the thermal energy to the heat exchanger 720. The thermal energy can be removed via conduits transporting a heating fluid (e.g., water). En route to the heat exchanger 720, the heating fluid can be temporarily stored in a heating fluid storage vessel 704. The heating fluid storage vessel 704 can contain heating fluid having a temperature that is greater than, equal to, or less than the temperature of the photovoltaic module. The heat exchanger 720 can be thermally connected to a heating and/or cooling apparatus 734 and a second heat exchanger 736. The second heat exchanger 736 can transport thermal energy to and from objects and/or structures that are to be cooled. The system may also include a controller 740. The controller 740 can monitor voltages, currents, temperatures, fluid flow rate and other values throughout the system 700. The controller 740 can also control fluid flow in the system 700. In an embodiment, the controller 740 controls pumps, valves, and/or fans in the heating and/or cooling apparatus 734 and/or the heat exchanger 736. The controller 740 can control the temperature, rate, and direction of fluid flow from the heating and/or cooling apparatus 734 via control connection 742. The controller 740 can control the temperature, rate, and direction of fluid flow from the heat exchanger 736 via the control connection 744. In an embodiment, the controller 740 controls a pump or valve controlling fluid flow between the heating fluid storage vessel 704 and the photovoltaic cogeneration unit 710. In an embodiment, the controller 740 provides surplus electricity, from the photovoltaic module, to the electric grid. In an embodiment, the controller 740 uses electricity from the electric grid to power the pumps, valves, and/or fans in the system 700.

In an embodiment, the photovoltaic cogeneration unit 710 can include a generator of an absorption chiller. Alternatively, thermal energy can be removed from the photovoltaic module and transported to the generator of the absorption chiller. In either case, the thermal energy from the photovoltaic cogeneration unit 710 may not be sufficient to boil the refrigerant and separate it from the absorbent in the generator. The first heating and/or cooling apparatus 734 can supplement this thermal energy by drawing a second amount of thermal energy from an external environment and transporting the second amount of thermal energy to the generator. In an embodiment, the first heating and/or cooling apparatus 734 can be a solar thermal collector.

It should be understood that the thermal conduits, heating fluid conduits, or arrows representing the flow of thermal energy, in FIGS. 1-7 represent various forms of thermal energy transfer. For instance, they can represent conduits or pipes wherein a fluid passes or circulates. Alternatively, they can represent interfaces between different materials. Alternatively, they can represent the transport of thermal energy through air via convection. This short list of examples is exemplary only, and one skilled in the art will recognize that various other means of thermal energy transfer can also be implemented.

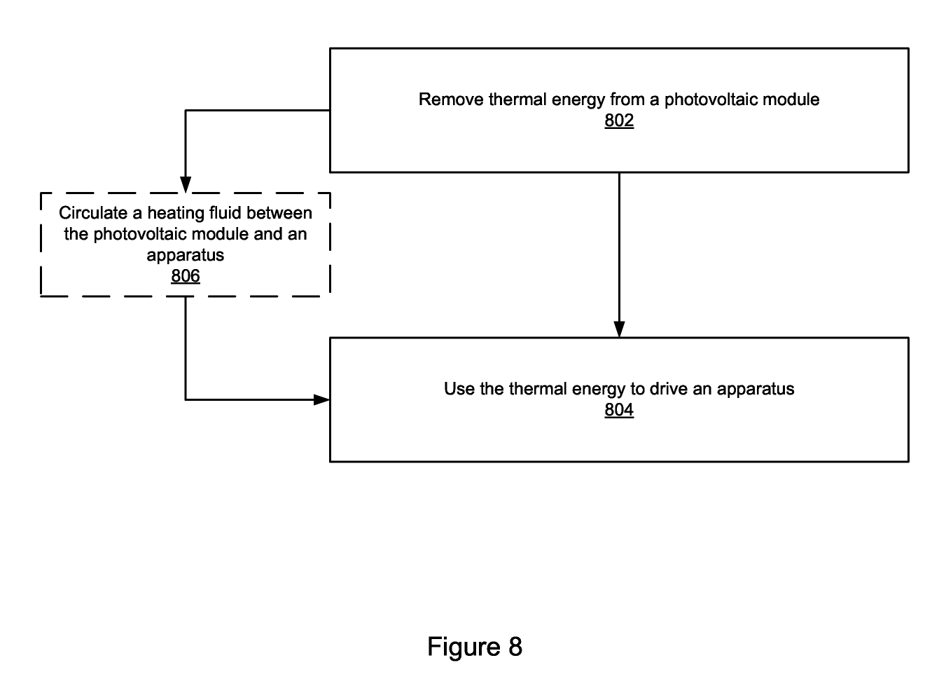

FIG. 8 illustrates a method 800 for cooling a solar module. The method 800 cools a solar module by removing thermal energy from the solar module and using the thermal energy to drive an apparatus. To do this, the method 800 includes a remove thermal energy from a photovoltaic module operation 802. The method 800 also includes a use thermal energy to drive an apparatus operation 804. Optionally the method 800 also includes a circulate a heating fluid between the photovoltaic module and an apparatus operation 806. It should be understood that the apparatus can be a cooling apparatus, a heating apparatus, or an apparatus configured to heat and/or cool a structure, object, or space.

Thermal energy can be removed from a photovoltaic module via any of the methods discussed earlier in this application. For instance, the thermal energy can be used to drive an apparatus such as an absorption chiller. The heating fluid can be circulated between the photovoltaic module and the apparatus in order to transport the thermal energy from the photovoltaic module to the apparatus. In an embodiment, the thermal energy can be absorbed in the generator of the absorption chiller. The thermal energy can boil a refrigerant out of a solution of refrigerant and absorbent in the generator. Alternately, the thermal energy can be absorbed in the heating fluid and transported to the generator of the absorption chiller via heating fluid conduits. Alternately, the thermal energy can be absorbed in a heating fluid and transported to one or more heat exchangers or heating fluid storage vessels. The heat exchangers can use the thermal energy to heat a structure, object, or space (e.g., home, office, pool). The heating fluid can be stored in one or more heating fluid storage vessels to be used at a later time.

It is clear that many modifications and variations of these embodiments may be made by one skilled in the art without departing from the spirit of the novel art of this disclosure. For example, the absorption chiller can use different refrigerants and absorbents than those explicitly mentioned above. As another example, the entire absorption chiller can be located on the roof of a home or other structure. While the above-discussed embodiments of absorption chillers included either water and lithium bromide or ammonia and water, other refrigerants and absorbents can also be used. For instance, one absorption chiller uses air, water, and a salt water solution. These modifications and variations do not depart from the broader spirit and scope of the invention, and the examples cited herein are to be regarded in an illustrative rather than a restrictive sense.

What is claimed is:

1. A system comprising:
a photovoltaic module configured to co-generate thermal energy;
a thermal path configured to remove a portion of the thermal energy from the photovoltaic module; and
an apparatus at least partially driven by the thermal energy from the thermal path.

2. The system of claim 1, wherein the apparatus is one of: a cooling apparatus, a heating apparatus, and an absorption chiller.

3. The system of claim 2, wherein the portion of the thermal energy is absorbed by a generator of the absorption chiller.

4. The system of claim 3, further comprising:
a thermal energy absorption enclosure configured to:
define a cavity enabling the passage of a heating fluid; and
convey the portion of the thermal energy from the photovoltaic module to the heating fluid.

5. The system of claim 4, wherein the heating fluid is a solution comprising water and antifreeze.

6. The system of claim 4, further comprising a warm heating fluid storage vessel configured to store the portion of the thermal energy.

7. The system of claim 3, further comprising a heat transfer unit connected to the absorption chiller and configured to:
remove a first amount of thermal energy from a condenser of the absorption chiller;
remove a second amount of thermal energy from an absorber of the absorption chiller; and
transfer the first amount of thermal energy and the second amount of thermal energy to an exterior environment.

8. The system of claim 3, wherein the absorption chiller comprises a refrigerant and an absorbent.

9. The system of claim 3, wherein:
a liquid absorbent-refrigerant solution enters the generator of the absorption chiller via a liquid absorbent-refrigerant input conduit;
a liquid absorbent leaves the generator via a liquid absorbent output conduit; and
a gaseous refrigerant leaves the generator via a gaseous refrigerant output conduit.

10. The system of claim 3, wherein the absorption chiller comprises:
a liquid absorbent-refrigerant input conduit configured to transfer a liquid absorbent-refrigerant solution from an absorber of the absorption chiller to a generator of the absorption chiller;
a generator configured to:
absorb the thermal energy from the photovoltaic module;
transfer the thermal energy into the liquid absorbent-refrigerant solution; and
separate the liquid absorbent-refrigerant solution into a gaseous refrigerant and a liquid absorbent;
an absorber;
a condenser;
a liquid absorbent output conduit configured to transfer the liquid absorbent from the generator to the absorber; and
a gaseous refrigerant output conduit configured to transfer the gaseous refrigerant from the generator to a condenser.

11. The system of claim 2, wherein the absorption chiller comprises water as a refrigerant and lithium bromide as an absorbent.

12. The system of claim 1, wherein the thermal path comprises a conductive material.

13. The system of claim 1, wherein the apparatus adjusts a temperature of the photovoltaic module to improve efficiency of the photovoltaic module in generating electricity.

14. An apparatus comprising:
a photovoltaic module that generates electricity and thermal energy;
a thermal energy absorption enclosure in contact with the photovoltaic module and configured to enable a heating fluid to:
enter the thermal energy absorption enclosure at a first temperature;
absorb a portion of the thermal energy; and
leave the thermal energy absorption enclosure at a second temperature, wherein the second temperature is higher than the first temperature.

15. The apparatus of claim 14, further comprising:
at least one heating fluid input conduit configured to transport the heating fluid at the first temperature into the thermal energy absorption enclosure; and
at least one heating fluid output conduit configured to transport the heating fluid at the second temperature out of the thermal energy absorption enclosure.

16. The apparatus of claim 15, wherein the thermal energy absorption enclosure is a generator of an absorption chiller.

17. The apparatus of claim 14, wherein the heating fluid transports the portion of the thermal energy to a heating and cooling apparatus, wherein the heating and cooling apparatus uses the portion of the thermal energy to drive a cooling cycle.

18. A method comprising:
removing thermal energy from a photovoltaic module; and
using the thermal energy to drive an apparatus.

19. The method of claim 18, further comprising:
circulating a heating fluid between the photovoltaic module and the apparatus in order to transport the thermal energy from the photovoltaic module to the apparatus.

20. The method of claim 18, wherein the using includes:
boiling a refrigerant out of a solution of refrigerant and absorbent in a generator of an absorption chiller.
